(19) United States
(12) Patent Application Publication
(10) Pub. No.: US 2002/0166569 A1
(43) Pub. Date: Nov. 14, 2002

(54) Method and apparatus for semiconductor wafer cleaning

(75) Inventors: Ellis Harvey, Chandler, AZ (US); Yakov Epshteyn, Phoenix, AZ (US); Frank Krupa, Phoenix, AZ (US)

Correspondence Address: Laura J Zeman, Snell & Wilmer LLP, One Arizona Center, 400 East Van Buren, Phoenix, AR, 85004-2202, US

(73) Assignee: SpeedFam-IPEC Corporation

(21) Appl. No.: 09/852,957

(22) Filed: May 10, 2001

(51) Int. Cl. B08B 3/04; H01L 21/302; H01L 21/461; B08B 3/12

(52) U.S. Cl. 134/1.3; 438/704; 438/707; 134/33; 134/138; 134/902; 134/147

(57) ABSTRACT

An apparatus and method for cleaning of disc-shaped objects, such as semiconductor wafers, employing a rotational fluid track. The cleaning may take place in a vertical cleaning chamber or optionally a horizontal cleaning chamber. Rotation of wafers is obtained without direct contact by motorized driver rollers that may have the potential of damaging the wafer. In preferred embodiments of the invention, a viscous shearing force is tangentially directed upon the surface of a wafer as the wafer rests upon support rollers within a cleaning chamber. Pressurized cleaning solutions are directed toward the wafer surface at an angle sufficient to impart a rotational force upon the wafer. In one embodiment of the invention, as the wafer spins within the cleaning chamber, a megasonic cleaning transducer is employed to enhance the surface cleaning process.

### FIELD OF INVENTION

The invention relates to the fabrication of semiconductors, and in particular, to a method and apparatus for cleaning silicon wafers.

### BACKGROUND OF THE INVENTION

In the fabrication of semiconductor devices, a disc-shaped silicon wafer is subjected to a variety of processes to create integrated circuits on its surface. At various stages during semiconductor fabrication, the wafer is subjected to polishing for planarization, followed by post-polishing cleaning before additional layered structures can be formed on each semiconductor of the wafer. Post-polishing cleaning is necessary to remove residual contaminants on the wafer surface that would result in defective integrated circuit structures.

Chemical mechanical polishing or “CMP” is often used in the industry for polishing to planarize the wafer structures and to selectively remove portions of layers or entire layers. The CMP process generally utilizes a slurry of finely divided particles suspended in a solution that is fed onto a pad during the polishing process. The slurry produces a chemical interaction with the wafer surface and also a mechanical interaction through abrasives present in the chemistry. Other polishing processes may use “fixed abrasive” pads, and not a slurry. When the polishing is carried out using CMP, or another technique, a polished surface will become contaminated with fine particulates (from the slurry or debris produced by polishing) and other minute contaminants. These contaminants must be removed to prevent potential for interference with the electrical circuitry being formed on the wafer. Therefore, after polishing, the semiconductor wafers must undergo a surface cleaning process to remove the contaminants.

### SUMMARY OF THE INVENTION

The present invention provides a unique apparatus and method for non-contact cleaning of workpieces, such as flat panels, data storage disks, lenses, semiconductor wafers, and the like. However, the descriptions refer mainly to semiconductor wafers. In accordance with the invention, cleaning of a wafer is carried out without physical contact of the wafer surface with a solid object, such as cleaning brushes. Rather, a wafer is at least partially submerged in a cleaning fluid, in a chamber containing at least one jet nozzle that imparts a rotational motion to the wafer. When a megasonic transducer is further employed in the chamber, the rotation of the wafer appears to minimize alternating bands of clean and non-clean section along the wafer surface induced by the megasonic waves.

In one aspect, a method of the invention employs a fluid to generate a force tangential to a semiconductor wafer surface of sufficient magnitude to rotate the wafer, which has been restrained within a chamber from other than rotational movement. In accordance with this method, the tangential force causing the wafer to rotate may be created by employing at least one pair of jet nozzles directed onto the wafer surface. Each jet nozzle may be arranged to strike at a location about equidistant from the center of the wafer, and in opposing directions. Optionally, only one jet nozzle may be employed at an angle to the surface of the wafer to impart a force striking the wafer sufficient to rotate the wafer.

In accordance with the invention, the force striking the wafer is applied continuously throughout the cleaning cycle, or optionally the force may intermittently strike the wafer. In either method, the force is of a sufficient magnitude to rotate the wafer.

According to another aspect of the invention, jet nozzles are arranged in a circular pattern around the outer circumference of a wafer. The nozzles are directed toward the surface of the wafer to impart a shearing force of sufficient magnitude to rotate the wafer.

In another aspect of the invention, jet nozzles are spaced along a locus of a diameter of the wafer, when the wafer is in the cleaning chamber, and directed to eject fluid forces in opposing directions to regions of the surface of the wafer.

In yet another aspect of the invention, the jet nozzles are arranged to direct a rotational vector to the wafer from the upper and lower surfaces of the wafer. In each of the aspects of the invention, a megasonic transducer may optionally be employed to enhance the surface cleaning of the wafer.

### BRIEF DESCRIPTION OF THE DRAWINGS

A more complete appreciation of the invention and its improvements can be obtained by reference to the accompanying drawings, which are illustrative of embodiments of the invention briefly summarized below. The drawings are not to scale and are intended for use in conjunction with the explanations in the following Detailed Description Section and to the appended claims.

FIG. 1 is a schematic view of a cleaning chamber as an exemplary embodiment of the invention;

FIG. 2 is a cross-sectional view of the cleaning chamber of FIG. 1;

FIG. 3 is a schematic view of another embodiment incorporating a circular manifold;

FIG. 4 is a schematic side view of yet another embodiment incorporating a linear manifold;

FIG. 5 is a schematic view of yet another embodiment incorporating a single nozzle;

FIG. 6 is a schematic side view of a horizontal cleaning chamber as still another embodiment; and

FIG. 7 is a schematic side view of another embodiment for a horizontal cleaning chamber, in accordance with the invention.

### DETAILED DESCRIPTION OF THE PREFERRED EMBODIMENT

In the following detailed description of exemplary embodiments of the invention, reference is made to the accompanied drawings, which form a part hereof, and which are shown by way of illustration, specific exemplary embodiments of which the invention may be practiced. These embodiments are described in sufficient detail to enable those skilled in the art to practice the invention, and it is to be understood that other embodiments may be utilized, and other changes may be made, without departing from the spirit or scope of the invention. The following detailed description is, therefore, not to be taken in a limiting sense, and the scope of the invention is defined only by the appended claims. Referring to the drawings, like numbers indicate like parts throughout the views.

Overview of Method of Operation

The present invention provides a non-contact method of cleaning workpieces, such as flat panels, data storage disks, lenses, semiconductor wafers, and the like, that have undergone prior processes leaving the wafer surfaces in a condition requiring cleaning before further processes can be carried out. The following descriptions however, refer mainly to semiconductor wafers. Typically, after a semiconductor wafer has undergone chemical mechanical polishing, or other polishing techniques, the wafer surface is cleaned to remove polishing debris and other particulates before commencing a next step in semiconductor fabrication. Often, the cleaning of the wafer is carried out in an apparatus that contains brushes, whether a circular or cylindrical, that contacts the wafer surface and assists in removing residual particulates to produce a cleaned wafer. However, whenever a wafer surface is so contacted, there is a risk that particulates entrained in the brushes may scour or scratch the wafer surface, potentially damaging semiconductor circuitry, or that uneven pressure between brushes on opposing sides of the wafer may result in catastrophic wafer damage.

In accordance with the invention, cleaning is carried out without physical contact of the wafer surface with a solid object, such as cleaning brushes. Rather, the wafer is at least partially submerged in a cleaning fluid, in a container sized for receiving the wafer. Desirably, the wafer is supported on wafer support rollers, arranged in an array to contact only peripheral edges of the wafer. The supports are further arranged to prevent other than rotational motion of the wafer, once it is firmly seated on the supports. In accordance with the invention, to facilitate cleaning, a megasonic transducer is introduced into the cleaning fluid, and the wafer surface is subjected to megasonic waves. As is known, a megasonic transducer will generate fine bubbles in a cleaning solution, and these bubbles travel to the wafer surface. As the bubbles migrate upward along the wafer surface, bubble scouring action assists in cleaning of the wafer surfaces. However, these megasonic waves tend to create alternating bands of clean and not-very-clean sections extending vertically upward along the wafer surface. These bands appear to result from bubbles selectively attaching to and scouring certain bands of the wafer surface as they migrate upward, while not attaching in as great numbers to other portions of the wafer surface that consequently are not as cleanly scoured.

In accordance with the invention, rotational motion is imparted to a wafer so that when megasonic waves are applied, the “band effect” described above is minimized. By rotating the wafer, either at a slow continuous speed or at intermittent intervals, the band issue is virtually eliminated and a substantially cleaner wafer may be obtained in a shorter period of time. Rotation of the wafer may be carried out by “non contact” means so that the wafer is not contacted with brushes, and the like. Rather, regions of the wafer are impacted with liquid ejected from a nozzle to impart forces tangential or parallel to the wafer surface of sufficient magnitude to induce rotational movement of the wafer on the wafer supports. The liquid used may be cleaning fluid, thereby permitting additional cleaning through the impact of the pressurized cleaning fluid. Alternatively, deionized water may be employed to provide the motive fluid. As explained in more detail below, to prevent damage to the wafers, especially larger 300 mm diameter wafers, it is preferred to apply fluid force to a wafer in equal magnitudes to opposed sides of the wafer, so that the opposing forces perpendicular to the wafer are balanced out, and the force vectors parallel to the surface of the wafer are of sufficient magnitude to rotate the wafer.

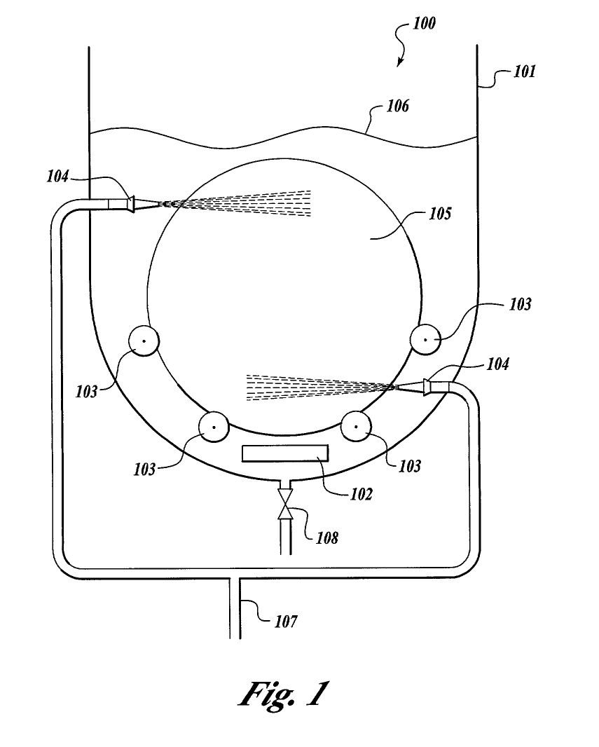

The invention may be better understood with reference to FIG. 1 that illustrates a schematic side view of a vertical cleaning apparatus 100, as an exemplary embodiment of the invention. In this embodiment, a semiconductor wafer 105 rests with its peripheral edges upon a plurality of support rollers 103 arranged in a circular array within a cleaning chamber 101. The support rollers 103 are preferably, but not necessarily, adjustable to accommodate a variety of semiconductor wafer 105 diameters. The cleaning chamber 101 may be of sufficient size and dimension such that a wafer 105 may be completely submerged within a cleaning solution 106. However, in the invention, complete submergence of the wafer is not essential.

A pressurized cleaning solution 106 is delivered through a cleaning solution supply line 107 to each of a plurality of jet nozzles 104. The cleaning solution 106 may be a chemical cleaning solution such as ammonium hydroxide, hydrochloric acid (HCl), hydrogen fluoride (HF), hydrogen peroxide (H₂O2), an acidic or alkaline peroxide mixture, potassium hydroxide (KOH), or other agents that may be used in the CMP industry. For example, the cleaning solution may be deionized water. The jet nozzles 104 are arranged in a manner and at such an angle that a viscous shearing force is created with a vector tangential to the surface of the wafer 105. This force vector causes the wafer 105 to move, rolling on the support rollers 103 and in effect causes it to rotate about its center. The cleaning solution 106 may either be removed immediately through the drain valve 108 located at the base of the cleaning chamber 101, or allowed to accumulate until the cleaning chamber 101 is filled and later removed.

Where the cleaning solution 106 is allowed to accumulate, a megasonic transducer 102 may be deployed in the cleaning chamber 101 to enhance surface cleaning of the wafer 105. In the example shown in FIG. 1, the transducer is centered directly beneath the support rollers 103 and the semiconductor wafer 105. The megasonic transducer 102 produces bubbles within the cleaning solution 106, which enhances the cleaning of the semiconductor wafer 105 by attaching to and scouring the wafer surface. Rotation of the wafer eliminates any vertical streaking created by the use of the megasonic transducer 102. This is an important benefit since it has been found now that wafers cleaned by megasonic techniques alone often have a surface pattern of alternating bands of clean and dirty sections on the wafer surface. Rotation, without physical contact with a brush, but solely with fluid force, eliminates the streaking and avoids risk of wafer damage due to debris entrapped on brushes or uneven brush pressure on opposite sides of the wafer.

In another embodiment of the invention, the jet nozzles 104 may operate non-continuously. A short, timed pulse of viscous shearing force could be used to rotate the wafer periodically during the cleaning. For example, the wafer 105 could be loaded into the cleaning chamber 101. Then the cleaning solution 106 could at least partially fill the chamber. The megasonic transducer 102 could be deployed within the cleaning chamber 101, to enhance the cleaning step. At timed intervals, the jet nozzles 104 emit a jet of liquid of sufficient shearing force to rotate the wafer by some predetermined amount, such as 90 degrees. The cleaning could continue for a period, followed by another timed rotation of the wafer. This cycle continues for a sufficient amount of time to produce substantial cleaning of the wafer 105. The wafer 105 would then be unloaded and a new wafer loaded, to repeat the steps.

In light of this disclosure, it will be recognized by one skilled in the art that the jet of liquid emitted from the jet nozzles 104 could be replaced by a jet of gas or other fluid sufficient to create a shearing force to rotate the wafer, without departing from the spirit or scope of the invention.

When the wafer is not continuously rotated, the periods that the wafer is stationary and non-stationary may be selected to minimize the total cleaning time. In accordance with the invention, the period of non-rotation of the wafer may range from about 5 seconds to about 60 seconds, followed by period of rotation ranging from 1 second to about 60 seconds.

The duration of total time in the cleaning chamber for a wafer may depend upon the degree the wafer has been contaminated. Nevertheless, the expected duration of cleaning for a wafer is about 20 to about 120 seconds.

Overview of Apparatus of the Invention

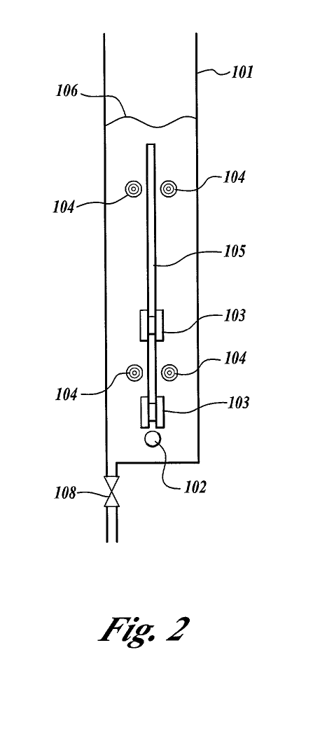

An overview of the apparatus of the invention may be obtained by reviewing an exemplary embodiment of the invention shown in FIG. 1 and FIG. 2. In these figures, the set of jet nozzles 104, described earlier, are arranged so that one pair of nozzles is located near the upper region of the wafer 105 when the wafer is resting on the support rollers 103. A second set of jet nozzles 104 is located near the lower region of the wafer 105. Each set of jet nozzles 104 may consist of two nozzles, arranged such that one of the nozzles is directed to spray solution on the front of the wafer's planar surface, and the other nozzle is directed to spray solution on the back of the wafer. The nozzles are arranged so that upper set of jet nozzles 104 are aimed about in a parallel but opposing direction to the lower set of jet nozzles 104. Each of the jet nozzles 104 is angled towards the planar surface of the wafer to cause a viscous shearing force of ejected solution upon the wafer 105. The shearing force is sufficient to cause the wafer to spin about its center.

In accordance with the invention, the rotation of the wafer caused by the applied shearing force from the jet nozzles 104 may range from 1 to about 50 rpm. Jet nozzles 104 may consist of any projecting material resistant to corrosion by cleaning solutions and is preferably tapered or constricted to accelerate or direct a flow of fluid through its orifice.

The jet nozzles 104 are connected to the cleaning solution supply line 107 from which solution is pumped to the nozzles under controlled pressure. Pressure at the nozzle may range from 10 to about 150 psig.

The megasonic transducer 102 is situated within the cleaning chamber 101 and located to apply sonic waves to the wafer for cleaning as described earlier.

Located in the bottom of the cleaning chamber 101, is a cleaning solution drain valve 108, to accommodate removal of the cleaning solution 106 and contaminants from the chamber. In one embodiment, the base of the cleaning chamber 101 is equipped with at least one fast acting valve (not shown). The fast acting value, controls the flow rate of liquid from the chamber and to a holding tank (not shown). A pump (not shown) pumps the solution through a micro filter (not shown), after which a particulate analyzer (not shown) monitors the particulate content of the solution in real time. A control system such as is used to control routing of the cleaning solution 106 back to the holding tank or to disposal. Based on input from the analyzer, the solution may be routed for disposal, or recycled to the holding tank for reuse during the cleaning process. Optionally, the temperature of the cleaning solution may be increased or even decreased to improve its effectiveness during reuse.

The apparatus of the invention, illustrated in FIG. 1 and FIG. 2, has the advantage of utilizing cleaning solutions already used during the cleaning process, thereby reducing the amount of potentially hazardous waste generated for disposal.

Additionally, the present invention has the advantage of eliminating the reliance on motorized drive rollers and direct contact rollers on the wafer 105.

Many wafer cleaning designs employ cleaning brushes that contact the surface of the wafer 105 to brush away contaminants. These brushes must then in turn be cleaned periodically to avoid re-contaminating the wafers. In addition, debris trapped on a brush can scour or scratch wafer surfaces. The present invention does away with the brushes, saving additional expenses and reducing the risk of damaged wafers.

The efficiency of the vertical cleaning chamber 101 may be enhanced by constructing the lower portion of the chamber in a cylindrical shape. The cylindrical shape removes corners in the chamber that create re-circulation zones in the fluid. An added advantage of the cylindrical shape of the lower region of the vertical cleaning chamber 101 is to improve the efficiency of the rotation of the wafer.

The invention is not limited to a single arrangement of the jet nozzles 104. In alternative embodiments, the jet nozzles 104 may be arranged in several possible configurations to produce a viscous shearing force sufficient to produce a rotational effect upon the wafer 105.

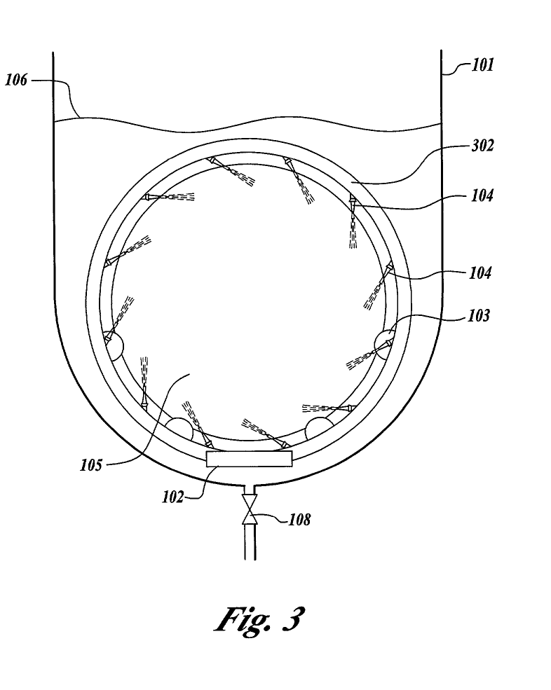

In one alternative embodiment of the invention, illustrated in FIG. 3, a plurality of jet nozzles 104 is arranged in a circular manifold 302. The jet nozzles 104 are arranged in a circular pattern around the outer circumference of the wafer 105 and directed toward the surface of the wafer at an angle sufficient to give rise to shearing forces of sufficient magnitude to rotate the wafer 105. An advantage of the circular manifold 302 is that it permits a reduction in the viscous shearing force required from the jet nozzles 104 thereby reducing the risk of damaging the wafers.

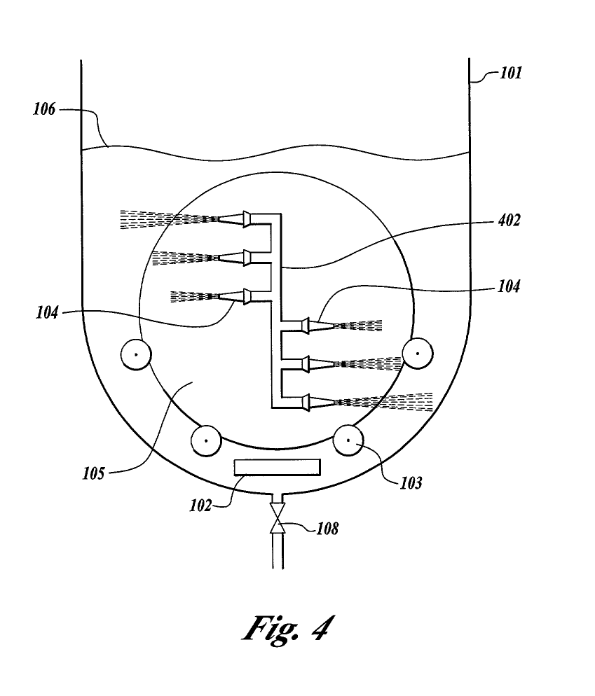

FIG. 4 illustrates yet another embodiment of the invention. In FIG. 4, a linear manifold 402 is employed to arrange a plurality of jet nozzles 104 in a linear arrangement. The jet nozzles 104 are arranged linearly across the surface of the wafer 105 to direct a plurality of viscous forces at various radial displacements of the wafer 105. Opposing jet nozzles 104 that are about equidistant from the center of the wafer 105 are directed in opposing directions so that when a viscous shearing force is delivered to the surface of the wafer, the wafer 105 rotates about its center.

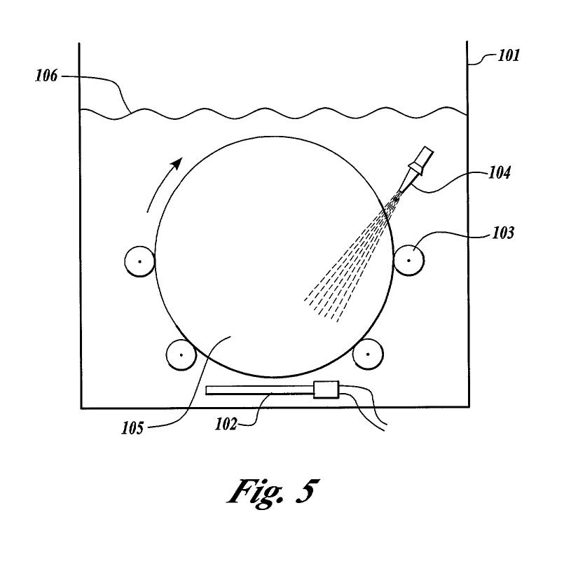

FIG. 5, is another embodiment of the invention and illustrates that the invention is not constrained to requiring several jet nozzles 104. A single jet nozzle 104 may be employed when properly directed toward the surface of the wafer 105 to deliver a viscous shearing force, causing rotation of the wafer 105.

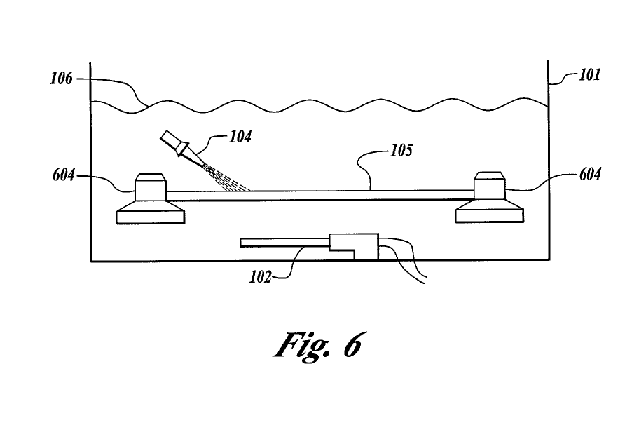

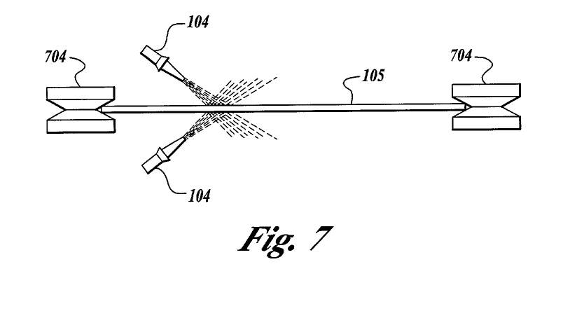

While a vertical cleaning chamber has the advantage of consuming less floor space, the present invention is not limited to vertical cleaning chambers. In FIG. 6, another embodiment of the invention illustrates the use of a horizontal cleaning chamber employing downward directed jet nozzles 104. Shown in FIG. 6, the wafer 105 rests upon a plurality of horizontal support rollers 604. In this arrangement, the jet nozzles 104 may be directed only upon the upper surface of the wafer 105 and has to generate sufficient fluid force at the wafer surface to cause it to rotate. However, as shown in FIG. 7, another embodiment would allow jet nozzles 104 to be directed on the lower surface as well. In this arrangement, the downward force produced by the upper surface jet nozzles 104 would balance the upward force produced by the lower surface jet nozzles 104, to avoid lifting the wafer from the horizontal notched support rollers 704. The horizontal notched support rollers 704 are designed to provide additional restraint allowing only rotational movement of the wafer 105 during the cleaning in the chamber.

The above specification, examples and data provide a complete description of the manufacture and use of the composition of the invention. Since many embodiments of the invention can be made without departing from the spirit and scope of the invention, the invention resides in the claims hereinafter appended.

We claim:

1. A method of cleaning semiconductor wafers, the method comprising:
(a) disposing a wafer in a chamber to restrain other than rotational wafer movement;
(b) striking at least one region of the wafer surface with a fluid to generate a force tangential to the wafer surface of sufficient magnitude to rotate the wafer; and
(c) cleaning the wafer.

2. The method of claim 1, wherein striking at least one region of the wafer comprises directing at least one pair of jet nozzles onto the wafer surface, each jet nozzle striking at a location about equidistant from the center of the wafer, the jet nozzles directed in opposing directions and force from the jet nozzles sufficient to cause the wafer to rotate about its center.

3. The method of claim 1, wherein the striking is with a fluid comprising deionized water, ammonium hydroxide, hydrochloric acid, hydrogen fluoride, hydrogen peroxide, or potassium hydroxide.

4. The method of claim 1, wherein disposing a wafer in a chamber to restrain the lateral displacement of the wafer comprises restraining with a plurality of wafer supports arranged within the chamber so that peripheral edges of the wafer contacts the supports, and the wafer rotates on the supports.

5. The method of claim 1, wherein striking the wafer causes rotation of the wafer at a rate of rotation about 1 to about 50 rpm.

6. The method of claim 1, wherein cleaning the wafer is for a period from about 1 to about 5 minutes.

7. The method of claim 1, wherein striking the wafer is intermittent and the wafer rotates intermittently.

8. The method of claim 1, wherein cleaning the wafer comprises applying a megasonic wave action to wafer surfaces.

9. A method of cleaning a workpiece comprising:
(a) subjecting the workpiece to megasonic waves in a container at least partially filled with liquid; and
(b) striking at least one region of the workpiece surface with a fluid force comprising a force vector parallel to the wafer surface, the force vector of sufficient magnitude to cause the workpiece to rotate.

10. The method of claim 9, wherein causing the workpiece to rotate comprises rotating the workpiece at a rate of rotation about 1 to about 50 rpm.

11. The method of claim 9, wherein striking the workpiece is intermittent and the workpiece rotates intermittently.

12. The method of claim 9, wherein the force vector striking the workpiece comprises a magnitude that may range from about 10 to about 150 psig.

13. A method of cleaning surfaces of semiconductor wafers, the method comprising:
(a) subjecting a wafer to megasonic waves in a chamber at least partially filled with liquid;
(b) directing a liquid to strike a surface of the wafer at a sufficient angle to the surface and with a velocity sufficient to induce a rotational movement of the wafer; and
(c) holding the wafer to restrain other than a rotational movement while the wafer is struck by the liquid.

14. An apparatus for cleaning a semiconductor wafer using a liquid cleaning solution, the apparatus comprising:
(a) a chamber sized for containing a wafer to be cleaned;
(b) a nozzle directing liquid to strike a surface of a wafer in the chamber with sufficient force to cause rotation of a wafer; and
(c) a plurality of wafer supports arranged in the chamber to allow a wafer to rotate thereon when the wafer is struck by liquid from the nozzle.

15. The apparatus of claim 14, wherein the chamber is sized for vertical placement of a wafer in the chamber.

16. The apparatus of claim 14, wherein the chamber comprises a base shaped to minimize formation of eddy currents in a liquid within the container.

17. The apparatus of claim 16, wherein the chamber base further comprises a lower portion, the lower portion being convexly shaped.

18. The apparatus of claim 14, wherein the chamber is sized for horizontal placement of a wafer in the chamber.

19. The apparatus of claim 14, wherein the wafer supports comprises notched support rollers.

20. The apparatus of claim 14, wherein the chamber further comprises a megasonic transducer centrally located within the chamber.

21. The apparatus of claim 14, further comprising an arrangement of nozzles, at least one directed toward a back surface of a wafer and at least one other directed to a front surface of the wafer.

22. The apparatus of claim 14, further comprising a plurality of nozzles arranged in a circular pattern with a circumference exceeding that of a wafer, the nozzles directed toward a surface of a wafer when placed in the chamber at an angle sufficient to give rise to shear forces of sufficient magnitude to rotate a wafer when a wafer is being cleaned in the apparatus.

23. The apparatus of claim 14, further comprising nozzles spaced along a locus of a diameter of a wafer, when a wafer is in the chamber, to direct viscous forces in opposing directions to regions of surfaces of a wafer.

24. The apparatus of claim 14, further comprising an arrangement of nozzles directed towards upper and lower regions of a front surface of a wafer, certain nozzles directed in opposite direction to other nozzles to thereby impart a rotational vector to a wafer during cleaning.

25. The apparatus of claim 14, wherein nozzle further comprising an arrangement of nozzles at a location about equidistant from the center of the wafer, the nozzles directed in opposing directions and force from the nozzles sufficient to cause the wafer to rotate about its center.

26. The apparatus of claim 14, wherein opposing force vectors perpendicular to a wafer surface, when a wafer is in the chamber, are balanced out at each region of fluid imparted on a wafer.

27. An apparatus for cleaning a workpiece comprising:
(a) a chamber sized for a workpiece to be cleaned;
(b) a megasonic wave transducer in the chamber at least partially filled with fluid; and
(c) a plurality of jet nozzles arranged in the chamber to create a force vector tangential to the workpiece surface, the force vector of sufficient magnitude to cause the workpiece to rotate.

28. A cleaning chamber for cleaning at least one semiconductor wafer, the chamber comprising:
(a) a container sized to contain a plurality of wafer support rollers, the container sufficiently deep to immerse the wafer therein in a liquid;
(b) a base of the container shaped to minimize formation of eddy currents in a liquid within the container; and
(c) a plurality of jet nozzles arranged in the container to create a force vector tangential to the wafer surface, the force vector of sufficient magnitude to cause the wafer to rotate.

29. The cleaning chamber of claim 28, wherein the container is sized for vertical placement of a wafer in the container.

30. The cleaning chamber of claim 28, wherein the base of the container comprises a lower portion, the lower portion being convexly shaped.

31. The cleaning chamber of claim 28, wherein the container is sized for horizontal placement of a wafer in the container.

32. The cleaning chamber of claim 28, wherein the container comprises a megasonic transducer centrally located within the container.

33. The cleaning chamber of claim 28, wherein the jet nozzles comprises an arrangement of nozzles, at least one directed toward a back surface of a wafer and at least one other directed to a front surface of the wafer.

34. The cleaning chamber of claim 28, wherein the jet nozzles comprises an arrangement of nozzles in a circular pattern with a circumference exceeding that of a wafer, the nozzles directed toward a surface of a wafer when placed in the container at an angle sufficient to give rise to shear forces of sufficient magnitude to rotate a wafer when a wafer is being cleaned in the apparatus.

35. The cleaning chamber of claim 28, wherein the jet nozzles comprises an arrangement of nozzles spaced along a locus of a diameter of a wafer, when a wafer is in the container, to direct viscous forces in opposing directions to regions of surfaces of a wafer.

36. The cleaning chamber of claim 28, wherein the jet nozzles comprises an arrangement of nozzles directed towards upper and lower regions of a front surface of a wafer, certain nozzles directed in opposite direction to other nozzles to thereby impart a rotational vector to a wafer during cleaning.
